(19) United States
(12) Patent Application Publication
(10) Pub. No.: US 2026/0101819 A1
(43) Pub. Date: Apr. 9, 2026

(54) SEMICONDUCTOR PACKAGE INCLUDING CONNECTION TERMINALS

(71) Applicant: SAMSUNG ELECTRONICS CO., LTD., Suwon-Si (KR)

(72) Inventor: Youngbae Kim, Suwon-si (KR)

(21) Appl. No.: 19/180,945

(22) Filed: Apr. 16, 2025

(30) Foreign Application Priority Data
Sep. 10, 2024 (KR) 10-2024-0123427

(51) Int. Cl. H01L 23/00; H01L 23/31; H01L 23/48; H01L 25/18; H10B 80/00

(52) U.S. Cl. CPC H10W 90/00; H10B 80/00; H10W 20/20; H10W 72/07353; H10W 72/227; H10W 72/334; H10W 74/111; H10W 74/15; H10W 90/722; H10W 90/732

(57) ABSTRACT

A semiconductor package includes a base chip, a plurality of memory chips disposed on the base chip, a sealing member disposed on the base chip and proximate to a side surface of the plurality of memory chips, and a plurality of connection terminals disposed on the bottom surface of the base chip opposite the plurality of memory chips, wherein a bottom surface of the base chip includes a first region and a second region disposed adjacent to the first region in the first direction, the plurality of connection terminals include a plurality of first connection terminals on the first region and a plurality of second connection terminals on the second region, and a first connection terminal of the plurality of first connection terminals is larger in size than a second connection terminal of the plurality of second connection terminals.

### CROSS-REFERENCE TO RELATED APPLICATION

This application is based on and claims priority under 35 U.S.C. § 119 to Korean Patent Application No. 10-2024-0123427, filed on Sep. 10, 2024, in the Korean Intellectual Property Office, the disclosure of which is incorporated by reference herein in its entirety.

### BACKGROUND

### 1. Technical Field

The inventive concept relates to a semiconductor package including connection terminals, and more particularly, to a semiconductor package including different sized connection terminals and having a structure in which semiconductor chips are stacked.

### 2. Discussion of Related Art

The rapid development of the electronics industry and user demands have led to the development of smaller and lighter electronic devices, together with the semiconductor packages used therein. These semiconductor packages typically need to have high reliability, high performance, and large capacity. To achieve these ends, development efforts are being directed towards semiconductor chips with through silicon via (TSV) structures and towards semiconductor packages having a structure in which the semiconductor chips may be stacked.

### SUMMARY

The inventive concept provides a semiconductor package with improved mountability.

In addition, aspects achieved by the inventive concept are not limited to aspects mentioned herein, and other aspects may be clearly understood by one of ordinary skill in the art from the following descriptions.

According to an aspect of the inventive concept, there is provided a semiconductor package including a base chip, a plurality of memory chips disposed on the base chip, a sealing member disposed on the base chip and proximate to a side surface of the plurality of memory chips, and a plurality of connection terminals disposed on the bottom surface of the base chip opposite the plurality of memory chips, wherein a bottom surface of the base chip includes a first region and a second region disposed adjacent to the first region in the first direction, the plurality of connection terminals include a plurality of first connection terminals on the first region and a plurality of second connection terminals on the second region, and a first connection terminal of the plurality of first connection terminals is larger in size than a second connection terminal of the plurality of second connection terminals.

According to another aspect of the inventive concept, there is provided a semiconductor package including a buffer chip, a plurality of memory chips arranged on the buffer chip, a sealing member disposed on the base chip and proximate to a side surface of the plurality of memory chips, and a plurality of connection terminals on the bottom surface of the buffer chip, wherein the plurality of connection terminals include a plurality of first connection terminals on a first region of a bottom surface of the buffer chip and a plurality of second connection terminals on a second region of the bottom surface of the buffer chip, the plurality of first connection terminals have a first pitch in a first direction and the plurality of second connection terminals have a second pitch in the first direction, the second pitch being less than the first pitch, and a first connection terminal of the plurality of first connection terminals is larger in size than a second connection terminal of the plurality of second connection terminals.

According to another aspect of the inventive concept, there is provided a semiconductor package including a package substrate, a first semiconductor device disposed on the package substrate, and at least one second semiconductor device disposed on the package substrate and adjacent to the first semiconductor device, wherein the second semiconductor device has a package structure including a base chip, a plurality of memory chips arranged on the base chip, a sealing member disposed on the base chip and proximate to a side surface of the plurality of memory chips, and a plurality of connection terminals disposed on a bottom surface of the base chip opposite the plurality of memory chips, wherein the plurality of connection terminals include a plurality of first connection terminals on a first region of the bottom surface of the base chip and a plurality of second connection terminals on a second region of the bottom surface of the base chip, and a first connection terminal of the plurality of first connection terminals is larger in size than a second connection terminal of the plurality of second connection terminals.

### BRIEF DESCRIPTION OF THE DRAWINGS

Embodiments of the inventive concept will be more clearly understood from the following detailed description taken in conjunction with the accompanying diagrams in which:

FIG. 1 is a cross-sectional view of a semiconductor package according to an embodiment;

FIG. 2A and FIG. 2B are a bottom view and an enlarged view of the semiconductor package of FIG. 1;

FIG. 3A and FIG. 3B are cross-sectional views illustrating the mountability of a semiconductor package of a comparative example and a semiconductor package of FIG. 1;

FIG. 4A, FIG. 4B, and FIG. 4C are a cross-sectional view and bottom views of a semiconductor package according to embodiments;

FIG. 5A and FIG. 5B are a perspective view and a cross-sectional view of a system package according to an embodiment;

FIG. 6A and FIG. 6B are perspective views illustrating the concept of an SoC or a chiplet included in the system package of FIG. 5A; and

FIG. 7A, FIG. 7B, FIG. 7C, and FIG. 7D are cross-sectional views of system packages according to embodiments.

### DETAILED DESCRIPTION

Hereinafter, embodiments of the inventive concept will be described in detail with reference to the accompanying drawings. The same reference numerals are used for the same components in the drawings, and redundant descriptions thereof may be omitted.

Semiconductor packages may generally experience warpage due to differences in coefficients of thermal expansion (CTE) between chips and a sealing member. A relatively large gap may be formed in a center portion between different layers of the semiconductor package during a mounting procedure, and the gap may increase a possibility of a mounting defect in connection terminals thereof. According to an embodiment, connection terminals of different sizes may be arranged between layers to be mounted to decrease the gap between the layers and decrease the possibility of a mounting defect. According to an embodiment, connection terminals of different sizes and having different pitches may be arranged between layers to be mounted to decrease the gap between the layers and decrease the possibility of a mounting defect.

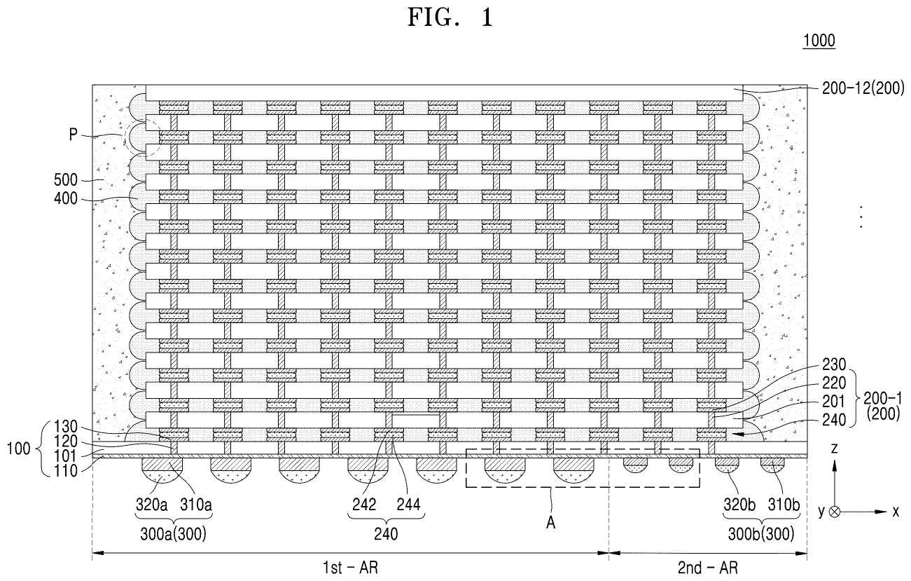

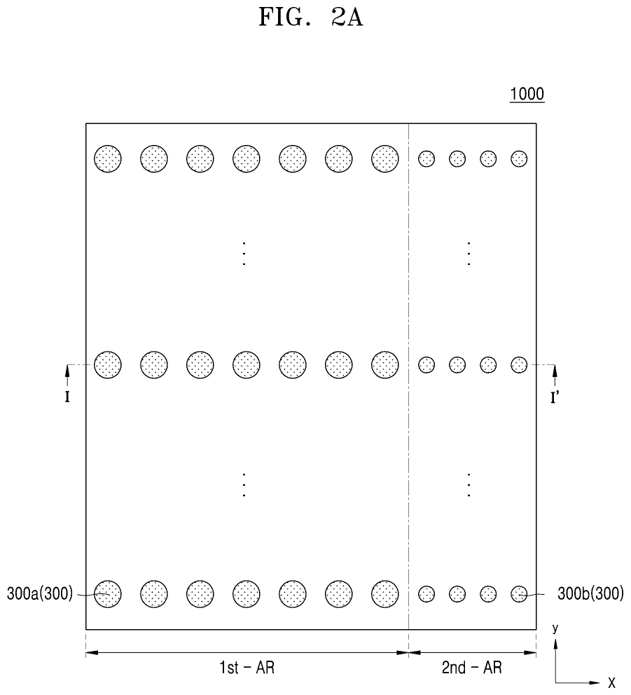

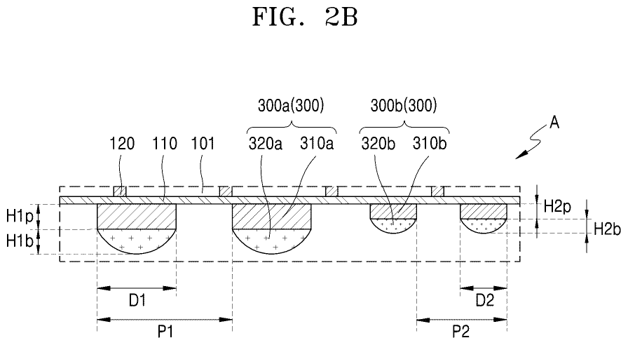

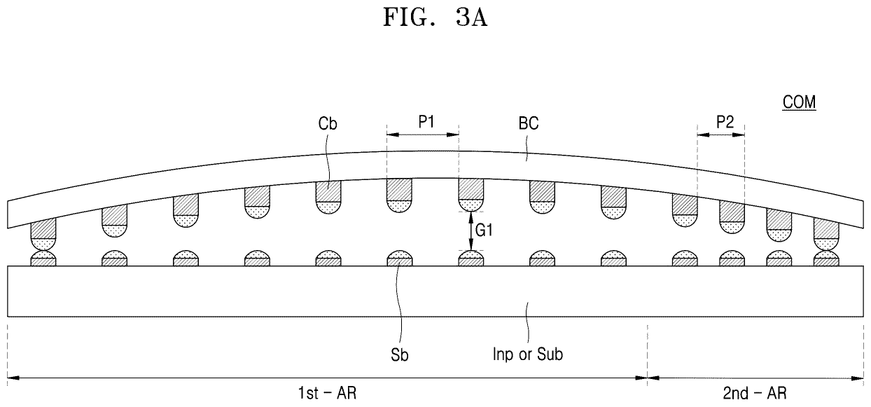

FIG. 1 is a cross-sectional view of a semiconductor package according to an embodiment, and FIG. 2A and FIG. 2B are a bottom view and an enlarged view of the semiconductor package of FIG. 1. FIG. 1 may correspond to a cross-sectional view taken along a line I-I′ of FIG. 2A.

Referring to FIG. 1, and FIG. 2A and FIG. 2B, a semiconductor package 1000 according to an embodiment may include a base chip 100, a plurality of memory chips 200, an external connection terminal 300, an adhesive layer 400, and a sealing member 500.

The base chip 100 may include a substrate body 101, an active layer 110, a through electrode 120, and an upper pad 130. The base chip 100 may have a larger size than the memory chips 200 arranged thereon, as shown in FIG. 1. However, the size of the base chip 100 is not limited thereto. For example, according to some embodiments, the base chip 100 may have substantially the same size as the memory chips 200. The term “substantially” as used herein means within an acceptable range of deviation for the particular value as determined by one of ordinary skill in the art. For example, “substantially” may mean within ±10%, 5%, or 1%.

The substrate body 101 may include, for example, a semiconductor element such as silicon (Si) or germanium (Ge). The substrate body 101 may include a compound semiconductor such as silicon carbide (SiC), gallium arsenide (GaAs), indium arsenide (InAs), or indium phosphide (InP). The substrate body 101 may have a silicon-on-insulator (SOI) structure. For example, the substrate body 101 may include a buried oxide (BOX) layer. The substrate body 101 may include a conductive region, for example, a structure such as a well doped with impurities or a source/drain region doped with impurities. The substrate body 101 may have various device isolation structures such as a shallow trench isolation (STI) structure.

The active layer 110 may include an integrated circuit layer and multiple wiring layers on the integrated circuit layer. The integrated circuit layer may include various types of devices. For example, the integrated circuit layer may include field effect transistors (FETs), such as a planar FET or a FinFET, memory devices such as a flash memory, dynamic random access memory (DRAM), static random access memory (SRAM), electrically erasable programmable read-out memory (EEPROM), phase-change random access memory (PRAM), magnetoresistive random access memory (MRAM), ferroelectric random access memory (FeRAM), or resistive random access memory (RRAM), logic devices such as an AND, an OR, or a NOT, or any of various active devices and/or passive devices such as a system large scale integration (LSI), a CMOS Imaging Sensor (CIS), or a Micro-Electro-Mechanical System (MEMS).

The multiple wiring layers may connect at least two devices to each other, connect devices to a conductive region of the substrate body 101, or connect devices to the external connection terminal 300. The multiple wiring layer may connect the through electrode 120 and the external connection terminal 300 to each other. The multiple wiring layers may include, for example, wiring lines and contacts or vias. In the semiconductor package 1000 according to an embodiment, the active layer 110 may be disposed below the through electrode 120. However, according to some embodiments, the active layer 110 may be disposed above the through electrode 120. For example, the positional relationship between the active layer 110 and the through electrode 120 may be relative.

In the semiconductor package 1000 according to an embodiment, the base chip 100 may include a plurality of logic devices in the integrated circuit layer of the active layer 110. The base chip 100 may be disposed below the memory chips 200. The base chip 100 may integrate signals from the memory chips 200 and transmit integrated signals to the outside. The base chip 100 may also transmit signals and power from the outside to the memory chips 200. Therefore, the base chip 100 may also be referred to as a buffer chip or an interface chip.

According to some embodiments, the base chip 100 may include a controller that controls signal transmission between the memory chips 200 and an external device. When the base chip 100 includes a controller, the base chip 100 may be referred to as a logic chip or a control chip. Also, according to some embodiments, the base chip 100 may include a power management integrated circuit (PMIC) that manages power or clock signals. Here, when the base chip 100 is referred to as a buffer chip, the memory chips 200 may be referred to as core chips.

In the semiconductor package 1000 according to an embodiment, the base chip 100 is not limited to a buffer chip or a logic chip. For example, the base chip 100 may include a number of memory devices in the integrated circuit layer of the active layer 110. Therefore, the base chip 100 may also include memory chips.

The through electrode 120 may penetrate through the substrate body 101 and extend from the top surface of the substrate body 101 to the bottom surface of the substrate body 101. According to some embodiments, the through electrode 120 may extend into the interior of the active layer 110. In the semiconductor package 1000 according to an embodiment, the substrate body 101 may include Si, and thus, the through electrode 120 may be referred to as a through silicon via (TSV).

The through electrode 120 may have a pillar-like shape and may include a barrier film on an outer surface and a buried conductive layer therein. The barrier film may include at least one material selected from among Ti, TiN, Ta, TaN, Ru, Co, Mn, WN, Ni, or NiB. The buried conductive layer may include at least one material selected from among Cu, Cu alloys such as CuSn, CuMg, CuNi, CuZn, CuPd, CuAu, CuRe, or CuW, W, W alloys, Ni, Ru, or Co. Also, an insulation layer may be disposed between the through electrode 120 and the substrate body 101 or between the through electrode 120 and the active layer 110. The insulation layer may include, for example, an oxide film, a nitride film, a carbide film, a polymer, or a combination thereof.

The upper pad 130 may be disposed on the top surface of the substrate body 101 and may be connected to the through electrode 120. The upper pad 130 may include, for example, at least one from among aluminum (Al), copper (Cu), nickel (Ni), tungsten (W), platinum (Pt), or gold (Au). In the semiconductor package 1000 according to an embodiment, the upper pad 130 may include Cu. However, the material constituting the upper pad 130 is not limited to Cu.

A protective layer may be disposed on the top surface of the substrate body 101 and the bottom surface of the active layer 110. The protective layer may include an insulation layer, for example, an oxide film, a nitride film, a carbide film, or a polymer, or a combination thereof. In the semiconductor package 1000 according to an embodiment, the protective layer may include, for example, a silicon oxide film, a silicon nitride film, or a silicon oxynitride film. However, the materials constituting the protective layer are not limited to the above-described materials. The through electrode 120 may extend through the protective layer, and the upper pad 130 may be disposed on the top surface of the through electrode 120. According to some embodiments, the upper pad 130 may be disposed on the top surface of the through electrode 120 in a structure that the upper pad 130 penetrates through the protective layer.

The memory chips 200 may be stacked on the base chip 100. In the semiconductor package 1000 according to an embodiment, twelve memory chips 200, for example, first to twelfth memory chips 200-1 to 200-12, may be stacked on the base chip 100. However, the number of memory chips 200 stacked on the base chip 100 is not limited to 12. For example, two to eleven memory chips 200 or thirteen or more memory chips 200 may be stacked on the base chip 100.

Here, in the semiconductor package 1000 according to an embodiment, the number of memory chips 200 may be 4n (n is a natural number). Therefore, the semiconductor package 1000 may include memory chips 200 in multiples of four, such as four, eight, or twelve. Also, every four memory chips 200 may have the same stack ID and may be tested and operated together. For example, when the semiconductor package 1000 includes twelve memory chips 200, first to fourth memory chips 200-1 to 200-4 may have a first stack ID, fifth to eighth memory chips 200-5 to 200-8 may have a second stack ID, and ninth to twelfth memory chips 200-9 to 200-12 may have a third stack ID. However, the semiconductor package 1000 according to an embodiment is not limited to the memory chips 200 in multiples of four and stack IDs corresponding thereto. For example, the semiconductor package 1000 according to an embodiment may include the memory chips 200 in multiples of two and stack IDs corresponding thereto or may include the memory chips 200 in multiples of eight and stack IDs corresponding thereto.

As illustrated, the memory chips 200 may have the same size and the same structure. However, embodiments are not limited thereto, and as shown in FIG. 1, the topmost memory chip from among the memory chips 200, e.g., the twelfth memory chip 200-12, may not include a through electrode. For convenience, descriptions will be given below based on the first memory chip 200-1.

The first memory chip 200-1 may include a body layer 201, a through electrode 220, an upper pad 230, and an inter-chip connection terminal 240. The body layer 201 may include a substrate body and an active layer. The substrate body may be substantially the same as the substrate body 101 of the base chip 100 described herein.

The active layer of the body layer 201 may include a plurality of memory devices. For example, the active layer may include volatile memory devices such as DRAM or SRAM, or non-volatile memory devices such as PRAM, MRAM, FeRAM, or RRAM. For example, in the semiconductor package 1000 of an embodiment, the first memory chip 200-1 may include DRAM devices in the active layer. Therefore, the first memory chip 200-1 may be a DRAM chip. Also, the first memory chip 200-1 may be a DRAM chip for high bandwidth memory (HBM). Therefore, the semiconductor package 1000 of an embodiment may be an HBM package. However, the semiconductor package 1000 according to an embodiment is not limited to an HBM package.

The through electrode 220 may penetrate through the substrate body of the body layer 201, or may penetrate the substrate body 101 and extend into the active layer 110. For example, when the first memory chip 200-1 is divided into a cell region and a pad region and the through electrode 220 is formed only in the pad region, the through electrode 220 may extend into the interior of the active layer by penetrating through the substrate body. The other descriptions regarding the through electrode 220 may be substantially the same as those of the through electrode 120 of the base chip 100 given herein.

The upper pad 230 is disposed on the top surface of the body layer 201 and may be connected to the through electrode 220. The upper pad 230 may be substantially the same as the upper pad 130 of the base chip 100 described herein, and a repeated description thereof may be omitted or simplified. Protective layers may be disposed on the top surface and the bottom surface of the body layer 201. The protective layers of the first memory chip 200-1 may be substantially the same as the protective layer of the base chip 100 described herein, and repeated descriptions thereof may be omitted or simplified.

The inter-chip connection terminal 240 may include a pillar 242 and a bump 244. The pillar 242 may include, for example, nickel (Ni), copper (Cu), palladium (Pd), platinum (Pt), or gold (Au), or a combination thereof. According to some embodiments, the pillar 242 may serve as a chip pad of the first memory chip 200-1 and may include Cu. Therefore, the pillar 242 may be referred to as a bump pad, a Cu-pad, or a Cu-pillar.

The bump 244 may be disposed on the pillar 242. The bump 244 may, for example, include solder. The solder may include tin (Sn), indium (In), bismuth (Bi), antimony (Sb), copper (Cu), silver (Ag), or zinc (Zn), and/or an alloy thereof. For example, the solder may include Sn, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn. According to some embodiments, the bump 244 may be referred to as a solder or a solder bump. An intermediate layer may be disposed at the contact interface between the pillar 242 and the bump 244. The intermediate layer may include an intermetallic compound (IMC) formed through a reaction between metal materials included in the pillar 242 and the bump 244 at a relatively high temperature.

The inter-chip connection terminal 240 may be similar to the external connection terminal 300 of the base chip 100. However, although the external connection terminal 300 is disposed on the bottom surface of the base chip 100, the inter-chip connection terminal 240 may be disposed between the first memory chip 200-1 and the base chip 100. In detail, the inter-chip connection terminal 240 may be disposed between a chip pad on the bottom surface of the body layer 201 of the first memory chip 200-1 and the upper pad 130 of the base chip 100. Also, each of the other memory chips 200 arranged above the first memory chip 200-1 may be stacked on a memory chip 200 directly therebelow through the inter-chip connection terminal 240. In other words, the inter-chip connection terminal 240 may be disposed between memory chips adjacent to each other in a vertical direction. As shown in FIG. 1, the inter-chip connection terminal 240 may have a size and a pitch less than those of the external connection terminal 300. Also, the inter-chip connection terminal 240 may have a thickness less than that of the external connection terminal 300. However, features such as the size, the pitch, or the thickness of the inter-chip connection terminal 240 are not limited thereto.

The external connection terminal 300 may be disposed on the bottom surface of the base chip 100. The external connection terminal 300 may be connected to the multiple wiring layer of the active layer 110. Also, the external connection terminal 300 may be electrically connected to the through electrode 120 through the multiple wiring layer. A chip pad may be disposed on the bottom surface of the base chip 100, and the external connection terminal 300 may be disposed on the chip pad. According to some embodiments, pillars 310a and 310b of the external connection terminal 300 may serve as chip pads. In such cases, no separate chip pad may be formed.

The external connection terminal 300 may include a first external connection terminal 300a and a second external connection terminal 300b. The first external connection terminal 300a may be disposed in a first region 1st-AR on the bottom surface of the base chip 100, and the second external connection terminal 300b may be disposed in a second region 2nd-AR on the bottom surface of the base chip 100.

As shown in FIG. 2A, the first region 1st-AR may be disposed adjacent to the second region 2nd-AR in the x direction. For example, the first region 1st-AR may be positioned on the left in the x direction, and the second region 2nd-AR may be positioned on the right in the x direction and adjacent to the first region 1st-AR. The left and the right in the x direction are relative terms and may be interchanged. In other words, the first region 1st-AR may be disposed on the right in the x direction, and the second region 2nd-AR may be disposed on the left in the x direction. The first region 1st-AR may have a wider area than the second region 2nd-AR. However, the area relationship between the first region 1st-AR and the second region 2nd-AR is not limited thereto. Further, the first region 1st-AR may have a first width in the first direction, and the second region 2nd-AR may have a second width, and the second width may be less than the first width.

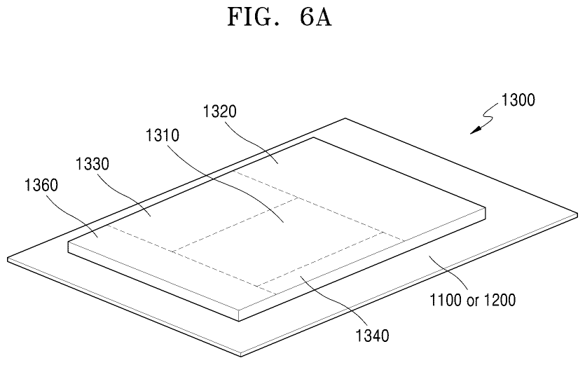

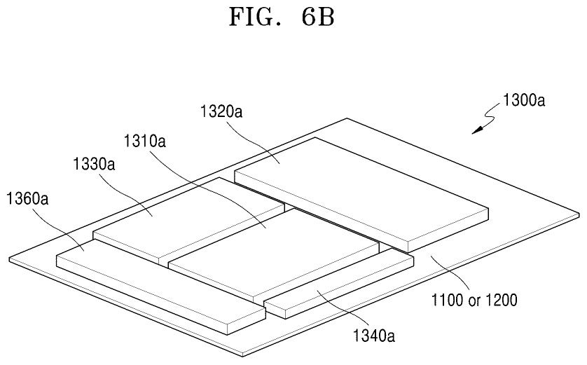

The second region 2nd-AR may be a region connected to an operation region within a logic chip or to a logic chip for operation. For example, when the semiconductor package 1000 is mounted on an interposer or a silicon (Si) bridge and connected to a semiconductor device (e.g., refer to 1300 of FIGS. 6A and 1300a of FIG. 6B) and a semiconductor device 1300 has a system-on-chip (SoC) structure, the second region 2nd-AR may be a region connected to an operation region, such as a CPU region or a GPU region, of the semiconductor device 1300. For example, the second external connection terminals 300b disposed in the second region 2nd-AR may be electrically connected to an operation region of a logic chip disposed on the base chip 100 in the second region 2nd-AR. Also, when a semiconductor device 1300a has a chiplet structure, the second region 2nd-AR may be a region connected to an operation logic chip, such as a CPU chip or a GPU chip, of the semiconductor device 1300a. With respect to the concept of a chiplet, according to some embodiments, the second region 2nd-AR may be referred to as a universal chiplet interconnect express (UCIe) region.

The first region 1st-AR may be a region other than the second region 2nd-AR. For example, the first region 1st-AR may be a region connected to a region other than the operation region within the logic chip of the semiconductor device 1300, or to a chip other than the operation logic chip of the semiconductor device 1300a.

For reference, an HBM package including a base chip with diversified designs and functions according to customization demands is called a custom HBM package. A UCIe region may be applied to a base chip of such a custom HBM package. Also, it is expected that the performance index of a custom HBM package considering bandwidth, memory capacity, and logic area cost is expected to be 2 to 5 times higher than those of existing HBM packages. In a custom HBM package having applied thereto a UCIe region, the pitch of external connection terminals of the first region 1st-AR may be different from the pitch of external connection terminals of the second region 2nd-AR. However, in the case of a typical custom HBM package, all of external connection terminals of the first region 1st-AR and the second region 2nd-AR have the same size, and the size of the external connection terminals usually corresponds to a small pitch. Therefore, the use of external connectors having the same size despite different pitches between regions may increase the possibility of mounting defects occurring in custom HBM packages. A mounting defect may include a crack in an interconnect or the failure of an interconnect.

In contrast, in the semiconductor package 1000 according to an embodiment, as described below, by using external connection terminals 300 having different sizes for different regions, the possibility of a mounting defect occurring in the semiconductor package 1000 may be reduced.

The first external connection terminal 300a may include a first pillar 310a and a first bump 320a. The second external connection terminal 300b may include a second pillar 310b and a second bump 320b. The first pillar 310a and the second pillar 310b each have a cylindrical shape and may include, for example, Ni, Cu, Pd, Pt, or Au, or a combination thereof. The first bump 320a is disposed on the first pillar 310a and may have a hemispherical shape. Also, the second bump 320b is disposed on the second pillar 310b and may have a hemispherical shape. The first bump 320a and the second bump 320b may each include, for example, solder. Materials constituting the solder may be the same as those of the bump 244 of the inter-chip connection terminal 240 described herein.

In the semiconductor package 1000 according to an embodiment, the first pillar 310a and the second pillar 310b may include Cu. Also, the first bump 320a and the second bump 320b may include solder. Therefore, the first pillar 310a and the second pillar 310b may be referred to as Cu-pillars. Also, the first bump 320a and the second bump 320b may be referred to as solders or solder bumps. Intermediate layers may be formed at the contact interface between the first pillar 310a and the first bump 320a and the contact interface between the second pillar 310b and the second bump 320b.

As shown in FIG. 2B, the first external connection terminal 300a may be larger in size than the second external connection terminal 300b. Also, first external connection terminals 300a may be arranged at a wider pitch than second external connection terminals 300b.

In detail, the first pillar 310a of the first external connection terminal 300a may have a first height H1p and a first diameter D1, and the first bump 320a may have a second height H1b and the first diameter D1. Also, the first external connection terminals 300a may be arranged in the first region 1st-AR at a first pitch P1. The second pillar 310b of the second external connection terminal 300b may have a third height H2p and a second diameter D2, and the second bump 320b may have a fourth height H2b and the second diameter D2. Also, the second external connection terminals 300b may be arranged in the second region 2nd-AR at a second pitch P2. The first height H1p may be greater than the third height H2p, and the second height H1b may be greater than the fourth height H2b. The first diameter D1 may be greater than the second diameter D2. Also, the first pitch P1 may be greater than the second pitch P2.

In detail, the third height H2p of the second pillar 310b may be about 15 μm, the fourth height H2b of the second bump 320b may be about 20 μm, and the second diameter D2 may be about 30 μm. Also, the second pitch P2 of the second external connection terminals 300b may be about 65 μm or less. The first external connection terminal 300a may have a size that is about 20% larger than that of the second external connection terminal 300b. For example, the first height H1p of the first pillar 310a may be at least about 20% greater than the third height H2p of the second pillar 310b, and the second height H1b of the first bump 320a may be at least about 20% greater than the fourth height H2b of the second bump 320b. The first diameter D1 of the first pillar 310a or the first bump 320a may be at least about 20% greater than the second diameter D2 of the second pillar 310b or the second bump 320b. Also, the first pitch P1 of the first external connection terminals 300a may be at least about 20% greater than the second pitch P2 of the second external connection terminals 300b. However, the sizes of the first external connection terminal 300a and the second external connection terminal 300b are not limited thereto. Also, the pitches of the first external connection terminals 300a and the second external connection terminals 300b are not limited thereto.

The term “about” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, or 5% of the stated value.

The adhesive layer 400 may be disposed between the base chip 100 and the first memory chip 200-1 and between two memory chips adjacent to each other and may cover inter-chip connection terminals 240. The adhesive layer 400 may include, for example, a non-conductive film (NCF). The NCF may be used, for example, as an adhesive layer when bonding semiconductor chips through thermal compression bonding (TCB) in a semiconductor chip stacking process. However, the material of the adhesive layer 400 is not limited to the NCF.

As shown in FIG. 1, side surfaces of the adhesive layer 400 may have a structure that protrudes from side surfaces of the memory chips 200. In other words, the adhesive layer 400 may include protrusions P, and the protrusions P may protrude from the side surfaces of the memory chips 200. The protrusions P of the adhesive layer 400 may be formed naturally due to the flowability of the adhesive layer 400 when the memory chips 200 are stacked through the TCB.

The protrusions P of the adhesive layers 400 adjacent to each other may be spaced apart from each other on the side surfaces of the memory chip 200. However, according to some embodiments, the protrusions P of the adhesive layers 400 adjacent to each other may be connected to each other on the side surfaces of the memory chips 200. The shape of a protrusion P of the adhesive layer 400 may be controlled by adjusting the viscosity of the adhesive layer 400 and temperature, pressure, time, etc. in the TCB process when the memory chips 200 are stacked through the TCB process.

In a semiconductor package according to some embodiments, the memory chips 200 may be stacked in a structure in which an adhesive layer is omitted. For example, in a case that the memory chips 200 are stacked through hybrid copper bonding (HCB), an adhesive layer may be omitted. Here, the HCB may mean a combination of pad-to-pad bonding and insulator-to-insulator bonding. In detail, in the memory chip 200, pads may be disposed on the bottom surface and the top surface of the memory chip 200, and the pads may be disposed to penetrate through protective layers arranged on the bottom surface and the top surface of the memory chip 200. A protective layer may include an insulator such as a silicon oxide film or a silicon nitride film. Therefore, pads and a protective layer on the top surface of a lower memory chip 200 may be combined with pads and a protective layer on the bottom surface of an upper memory chip 200 to form an HCB. Since pads usually include Cu, pad-to-pad bonding is also called Cu-to-Cu bonding.

Also, in a semiconductor package according to some embodiments, the memory chips 200 may not include through electrodes and inter-chip connection terminals. In a case that the memory chips 200 do not include through electrodes and inter-chip connection terminals, signal transmission between the memory chips 200 and the base chip 100 may be achieved, for example, through wireless communication. Therefore, each of the memory chips 200 and the base chip 100 may include devices for wireless communication.

The sealing member 500 may surround the memory chips 200. The sealing member 500 may be disposed on the base chip 100 proximate to a side surface of the memory chips 200. For example, the sealing member 500 may surround at least a portion of side surfaces of the memory chips 200 on the base chip 100. In detail, the sealing member 500 may surround at least a portion of side surfaces of the adhesive layer 400 between the base chip 100 and the first memory chip 200-1, at least a portion of the side surfaces of each of the memory chips 200, and at least a portion of the side surfaces of the adhesive layer 400 between the memory chips 200. As shown in FIG. 1, the sealing member 500 may not cover the top surface of a topmost memory chip, e.g., the twelfth memory chip 200-12. Therefore, the top surface of the twelfth memory chip 200-12 may be exposed from the sealing member 500. However, according to some embodiments, the sealing member 500 may cover the top surface of the topmost memory chip, e.g., the twelfth memory chip 200-12. The sealing member 500 may include, for example, an epoxy mold compound (EMC). However, the material of the sealing member 500 is not limited to the EMC.

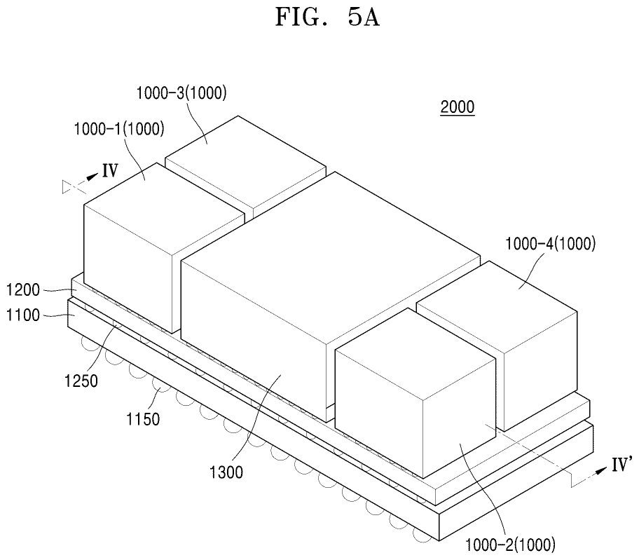

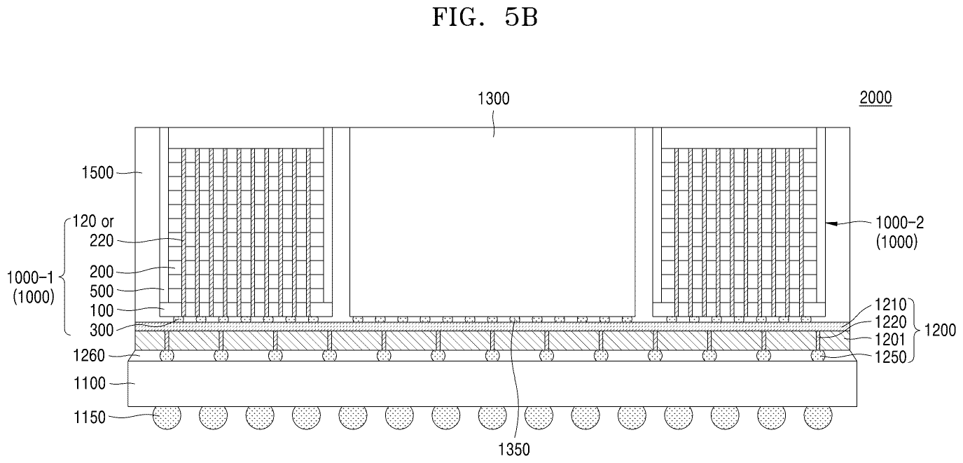

In the semiconductor package 1000 according to an embodiment, the external connection terminal 300 on the bottom surface of the base chip 100 may include the first external connection terminal 300a disposed in the first region 1st-AR and the second external connection terminal 300b disposed in the second region 2nd-AR. Also, the first external connection terminals 300a may be arranged at the first pitch P1 that is greater than the second pitch P2 of the second external connection terminals 300b, and the first external connection terminal 300a may have a size greater than that of the second external connection terminal 300b. In this regard, in a case that the first external connection terminals 300a have a larger size and are arranged at a greater pitch as compared to the second external connection terminals 300b, when the semiconductor package 1000 is mounted on a package substrate or an interposer, the mountability of the semiconductor package 1000 may be improved. As a result, the semiconductor package 1000 according to an embodiment may improve the yield by reducing the probability of mounting defects occurring in a system package (refer to 2000 of FIG. 5A, etc.) or a product including the semiconductor package 1000. Mountability may refer to the ability of semiconductor package 1000 to be mounted or attached to a surface, structure, or system. The mountability may be affected by a flatness of the semiconductor package 1000 or a stress in the semiconductor package 1000.

Also, the semiconductor package 1000 according to an embodiment may include the base chip 100 having diversified designs and functions according to customization demands, for example, the base chip 100 to which a UCIe region is applied. Therefore, the semiconductor package 1000 according to an embodiment may improve mountability on a package substrate or an interposer while adapting early to custom base chips or custom semiconductor packages in the future.

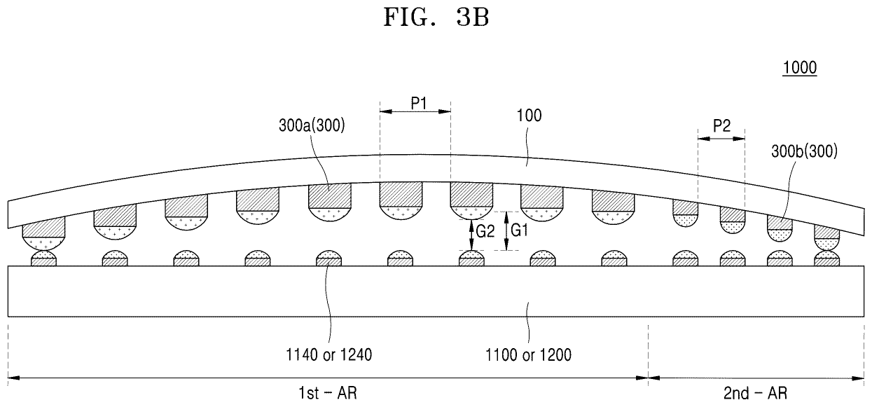

FIG. 3A and FIG. 3B are cross-sectional views illustrating the mountability of a semiconductor package of a comparative example and a semiconductor package of FIG. 1. Descriptions are given below with reference to FIG. 1, and descriptions given elsewhere herein may be briefly given or omitted. Here, FIG. 3A and FIG. 3B illustrate only base chips BC and 100 and a mounting substrate Inp or Sub of semiconductor packages for convenience.

Referring to FIG. 3A, in a semiconductor package COM of the comparative example, connection terminals Cb arranged on the bottom surface of a base chip BC may have the same size in both the first region 1st-AR and the second region 2nd-AR. Here, the first region 1st-AR and the second region 2nd-AR may be substantially the same as those described above with reference to FIG. 1 and FIG. 2A, and repeated descriptions thereof may be omitted or simplified. The connection terminals Cb may have the first pitch P1 in the first region 1st-AR and the second pitch P2 in the second region 2nd-AR. The first pitch P1 and the second pitch P2 may be substantially the same as those described above with reference to FIG. 2B.

As shown in FIG. 3A, semiconductor packages may generally experience warpage due to, for example, differences in coefficients of thermal expansion (CTE) between chips and a sealing member. For example, the CTE between the chips and the sealing member may generate a thermal stress in the semiconductor package COM, which may lead to fatigue failure and cracking of solder joints. Therefore, an effective gap, i.e., a first gap G1, may be formed between the semiconductor package COM and a mounting substrate Inp or Sub of the comparative example. Here, the mounting substrate Inp or Sub may include an interposer Inp or a package substrate Sub. Also, the effective gap of a semiconductor package COM may be defined as a greatest distance between connection terminals Cb of the base chip BC and opposite connection terminals Sb of a mounting substrate Inp or Sub when at least some of the connection terminals of the base chip BC and the mounting substrate Inp or Sub are in contact with each other. The opposite connection terminals Sb of the mounting substrate Inp or Sub may be substantially the same as the connection terminals Cb of the base chip BC. When the mounting substrate Inp or Sub is flat without warpage, the effective gap thereof may be substantially the same as the warpage of the base chip BC of the comparative example. However, since warpage may occur on the mounting substrate Inp or Sub, the effective gap thereof may be different from the warpage of the base chip BC of the comparative example.

When the first gap G1 is equal to or greater than an allowable effective gap and the semiconductor package COM of the comparative example is mounted on the mounting substrate Inp or Sub, a quality of the mount may deteriorate, and thus the possibility of a mounting defect occurring may increase. Here, the allowable effective gap may be, but is not limited to, about 20□ (micrometers). For example, the allowable effective gap may vary depending on the size of a semiconductor package, the number of memory chips to be stacked, or the material of a sealing member.

Referring to FIG. 3B, in the semiconductor package 1000 according to an embodiment, the first external connection terminals 300a may be arranged at the first pitch P1 in the first region 1st-AR, and the second external connection terminals 300b may be arranged at the second pitch P2 in the second region 2nd-AR. Also, the first external connection terminal 300a may be larger in size than the second external connection terminal 300b. For example, the sizes of the first external connection terminal 300a and the second external connection terminal 300b may be substantially the same as those described herein with reference to FIG. 2B. For example, in a case that the second external connection terminals 300b are shorter than the first external connection terminals 300a, a portion of the base chip 100 in the second region 2nd-AR may be closer to the mounting substrate 1100 or 1200 than any portion of the base chip 100 in the first region 1nd-AR. Therefore, in the semiconductor package 1000 according to an embodiment, an effective gap, i.e., a second gap G2, may be formed. As shown in FIG. 3B, the second gap G2 may be smaller than the first gap G1 of the comparative example. Also, the second gap G2 may be smaller than the allowable effective gap. For example, the first external connection terminal 300a and the second external connection terminal 300b have a height difference, shown as the second gap G2, sufficient to compensate for warpage of the base chip. Here, the second gap G2 may sufficiently compensate for the warpage by being less than the first gap G1. In an embodiment, the second gap G2 may sufficiently compensate for the warpage by decreasing the possibility of a mounting defect following a reflow to connect the first external connection terminal 300a and the second external connection terminal 300b with opposite connection terminals 1140 or 1240 of the mounting substrate 1100 of 1200. Therefore, when the semiconductor package 1000 according to an embodiment is mounted on a mounting substrate 1100 or 1200, the mountability may be improved, and the possibility of a mounting defect occurring may be reduced. A process of mounting the semiconductor package 1000 on the mounting substrate 1100 or 1200 may include a reflow process. In the reflow process, the first bump 320a and the second bump 320b may be melted during bonding, forming an electrical interconnect with the opposite connection terminals 1140 or 1240 of the mounting substrate 1100 or 1200. Here, the mounting substrate 1100 or 1200 may include a package substrate 1100 or an interposer 1200.

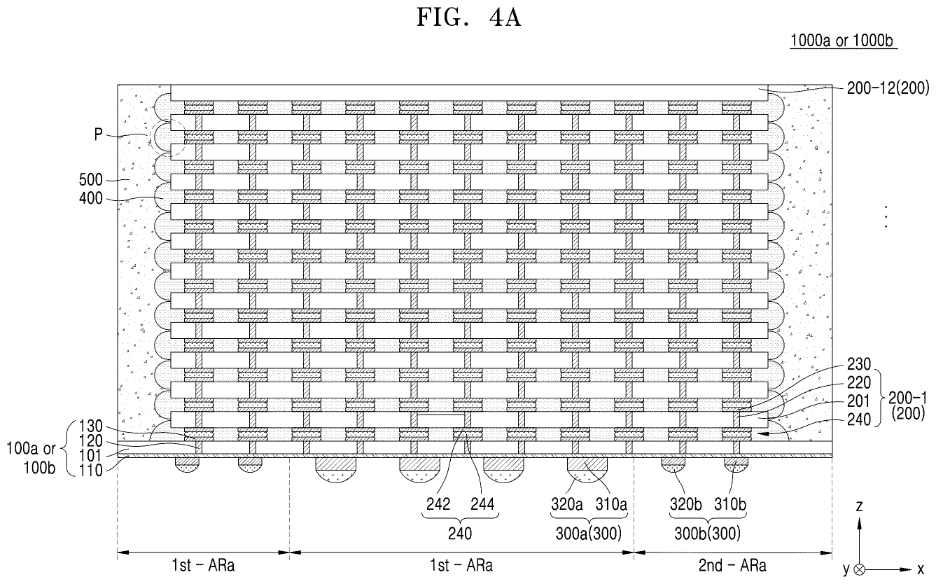

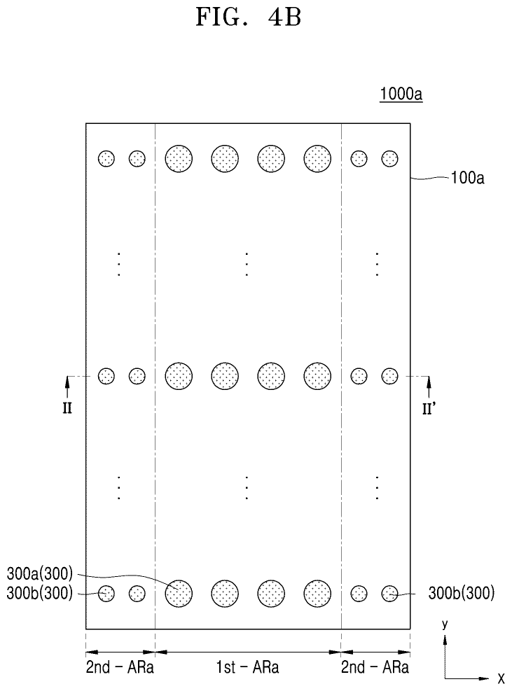

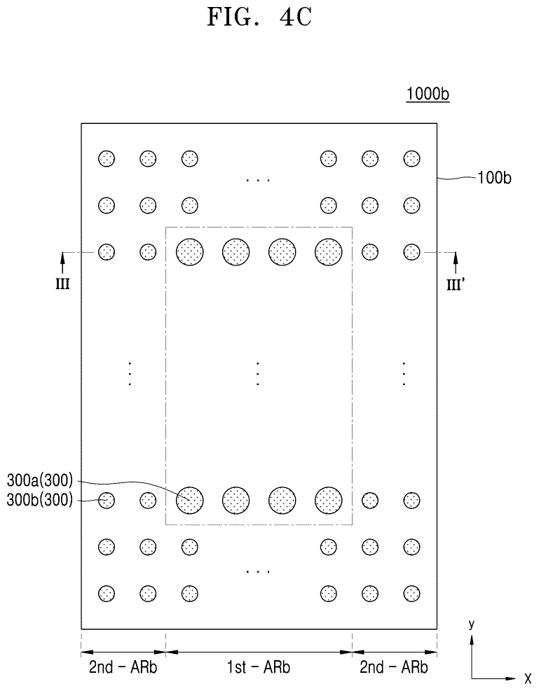

FIG. 4A, FIG. 4A, and FIG. 4C are a cross-sectional view and bottom views of a semiconductor package according to embodiments. FIG. 4A may correspond to a cross-sectional view taken along a line II-II′ of FIG. 4B or a line III-III′ of FIG. 4C. Descriptions given elsewhere herein may be briefly given or omitted.

Referring to FIG. 4A and FIG. 4B, a semiconductor package 1000a according to an embodiment may differ from the semiconductor package 1000 of FIG. 1 in the shape of a first region 1st-ARa and a second region 2nd-ARa of a base chip 100a. In detail, the semiconductor package 1000a according to an embodiment may include the base chip 100a, the plurality of memory chips 200, the external connection terminal 300, the adhesive layer 400, and the sealing member 500. The plurality of memory chips 200, the external connection terminal 300, the adhesive layer 400, and the sealing member 500 may be substantially the same as those described herein in the descriptions of the semiconductor package 1000 of FIG. 1, and repeated descriptions thereof may be omitted or simplified.

In the semiconductor package 1000a according to an embodiment, the base chip 100a may include the first region 1st-ARa located at a central portion of the base chip 100a in the x direction and the second region 2nd-ARa located at opposite outer portions of the base chip 100a in the x direction. In other words in a plan view, second regions 2nd-ARa may be arranged on the left side and the right side of the first region 1st-ARa in the x direction, respectively. The first external connection terminals 300a may be arranged in the first region 1st-ARa, and the second external connection terminals 300b may be arranged in the second region 2nd-ARa. The pitches and the sizes of the first external connection terminals 300a and the second external connection terminals 300b may be substantially the same as those described with reference to FIG. 2B. In the semiconductor package 1000a according to an embodiment, the first external connection terminal 300a having a large size may be arranged in the first region 1st-ARa in the center portion of the semiconductor package 1000a, and the second external connection terminals 300b having a small size may be disposed in second regions 2nd-ARa on both outer sides of the semiconductor package 1000a, and thus the mountability on the mounting substrate 1100 or 1200 may be improved. Therefore, a probability of the occurrence of a mounting defect of the semiconductor package 1000a according to an embodiment may be reduced, and the yield of a system package or a product including the semiconductor package 1000a may be improved.

Referring to FIG. 4C, a semiconductor package 1000b according to an embodiment may differ from the semiconductor package 1000 of FIG. 1 in the shape of a first region 1st-ARb and a second region 2nd-ARb of a base chip 100b. In detail, the semiconductor package 1000b according to an embodiment may include the base chip 100b, the plurality of memory chips 200, the external connection terminal 300, the adhesive layer 400, and the sealing member 500. The plurality of memory chips 200, the external connection terminal 300, the adhesive layer 400, and the sealing member 500 may be substantially the same those described herein in the descriptions of the semiconductor package 1000 of FIG. 1, and repeated descriptions thereof may be omitted or simplified. Also, the cross-sectional view of the semiconductor package 1000b according to an embodiment may be substantially to the same as that illustrated in FIG. 4A.

In the semiconductor package 1000b according to an embodiment, the base chip 100b may include the first region 1st-ARb located at the central portion of the base chip 100b in the x direction and the y direction and second regions 2nd-ARb located at outer portions of the base chip 100b in the x direction and the y direction. In other words, the second regions 2nd-ARb may surround the first region 1st-ARb in the x direction and the y direction. For example, in a plan view, the second regions 2nd-ARb may be arranged on the left side and the right side of the first region 1st-ARb in the x direction, and the second regions 2nd-ARb may be further arranged on the upper side and the lower side of the first region 1st-ARb in the y direction.

The first external connection terminals 300a may be disposed in the first region 1st-ARb, and the second external connection terminals 300b may be disposed in the second region 2nd-ARb. The pitches and the sizes of the first external connection terminals 300a and the second external connection terminals 300b may be substantially the same as those described herein with reference to FIG. 2B. In the semiconductor package 1000b according to an embodiment, the first external connection terminal 300a having a large size may be arranged in the first region 1st-ARb in the center portion, and the second external connection terminals 300b having a small size may be disposed in second regions 2nd-ARb on outer sides (e.g., four outer sides), and thus the mountability on the mounting substrate 1100 or 1200 may be improved. Therefore, a probability of the occurrence of a mounting defect of the semiconductor package 1000b according to an embodiment may be reduced, and the yield of a system package or a product including the semiconductor package 1000b may be improved.

Although descriptions are given herein based on a custom HBM package including a UCIe region as the second region 2nd-AR on the bottom surface of the base chip 100 has been exemplified, a semiconductor package according to an embodiment is not limited to a custom HBM package. For example, a semiconductor package according to an embodiment may include different types of HBM packages having a structure in which regions of different pitches may be defined on the bottom surface of the base chip 100 and external connection terminals of different sizes may be arranged in correspondence to the respective regions. Furthermore, a semiconductor package according to an embodiment may include, in addition to the HBM package, different types of semiconductor packages having a structure in which regions of different pitches may be defined on the bottom surface of a substrate or a chip at the lowest position of the semiconductor package and external connection terminals of different sizes may be arranged in correspondence to the respective regions.

FIG. 5A and FIG. 5B are a perspective view and a cross-sectional view of a system package, respectively, according to an embodiment. FIG. 5B may correspond to a cross-sectional view taken along a line IV-IV′ of FIG. 5A. FIG. 6A and FIG. 6B are perspective views illustrating the concept of an SoC or a chiplet included in the system package of FIG. 5A. Descriptions of FIG. 5A, FIG. 5B, FIG. 6A, and FIG. 6B are given below with reference to FIG. 1, and repeated descriptions given elsewhere herein may be briefly given or omitted.

Referring to FIGS. 5A and 5B and FIGS. 6A and 6B, a system package 2000 according to an embodiment may include the semiconductor package 1000, the package substrate 1100, the interposer 1200, the semiconductor device 1300, and an external sealing member 1500.

As shown in FIG. 5A, the semiconductor package 1000 may include a first semiconductor packages 1000-1, a second semiconductor packages 1000-2, a third semiconductor packages 1000-3, and a fourth semiconductor package 1000-4. For example, two semiconductor packages 1000 may be disposed on the interposer 1200 on each side of the semiconductor device 1300. However, in the system package 2000 of an embodiment, the number of semiconductor packages 1000 is not limited to four. For example, one to three semiconductor packages 1000 or five or more semiconductor packages 1000 may be arranged on the interposer 1200.

The semiconductor package 1000 may be, for example, the semiconductor package 1000 of FIG. 1. Therefore, the semiconductor package 1000 according to an embodiment may include the base chip 100, the memory chips 200, the external connection terminal 300, the adhesive layer 400, and the sealing member 500. The bottom surface of the base chip 100 may be divided into the first region 1st-AR and the second region 2nd-AR, and the external connection terminals 300 may include the first external connection terminals 300a arranged in the first region 1st-AR and the second external connection terminals 300b arranged in the second region 2nd-AR. The first external connection terminal 300a may have a size greater than that of the second external connection terminal 300b. The second external connection terminals 300b may be arranged on the second region 2nd-AR at the second pitch P2, and the first external connection terminals 300a may be arranged on the first region 1st-AR at the first pitch P1 that is greater than the second pitch P2. FIG. 5B, the semiconductor package 1000 is shown in a reduced form, and thus, for convenience, an adhesive layer and inter-chip connection terminals are not shown.

In the system package 2000 according to an embodiment, the semiconductor package 1000 may be, for example, a custom HBM package including a UCIe region as the second region 2nd-AR. However, the semiconductor package 1000 is not limited to a custom HBM package. The base chip 100 of the semiconductor package 1000 may be a buffer chip, and the memory chips 200 may each be a DRAM chip. In the system package 2000 according to an embodiment, the semiconductor package 1000 is not limited to the semiconductor package 1000 of FIG. 1. For example, instead of the semiconductor package 1000 of FIG. 1, a semiconductor package 1000a or 1000b of FIG. 4B or FIG. 4C may be applied to the system package 2000.

The package substrate 1100 is a support substrate, and the interposer 1200, the semiconductor package 1000, and the semiconductor device 1300 may be stacked on the package substrate 1100. The package substrate 1100 may include at least one layer of wiring lines therein. When wiring lines are formed in multiple layers, wiring lines of different layers may be connected to each other through vertical vias. The package substrate 1100 may include, for example, a ceramic substrate, a printed circuit board (PCB), an organic substrate, an interposer substrate, etc. First connection terminals 1150 may be arranged on the bottom surface of the package substrate 1100. The system package 2000 may be stacked on an external system board or a main board through the first connection terminals 1150.

The interposer 1200 may include an interposer substrate 1201, a wiring layer 1210, a through electrode 1220, and a second connection terminal 1250. The semiconductor package 1000 and the semiconductor device 1300 may be mounted on the package substrate 1100 via the interposer 1200. The interposer 1200 may connect the semiconductor package 1000 and the semiconductor device 1300 to each other. Also, the interposer 1200 may connect the semiconductor package 1000 and the semiconductor device 1300 to the package substrate 1100.

The interposer substrate 1201 may include, for example, Si. Therefore, the interposer 1200 may be a Si interposer. The through electrode 1220 may extend through the interposer substrate 1201. Since the interposer substrate 1201 includes Si, the through electrode 1220 may correspond to a TSV. The through electrode 1220 may extend to the wiring layer 1210 and be connected to wiring lines of the wiring layer 1210. According to embodiments, the interposer 1200 may include only a wiring layer therein and may not include through electrodes. The wiring layer 1210 may be disposed on the top surface or the bottom surface of the interposer substrate 1201. For example, the positional relationship between the wiring layer 1210 and the through electrode 1220 may be relative. Pads on the top surface of the interposer 1200 may be respectively connected to through electrodes 1220 through the wiring layer 1210.

The second connection terminal 1250 may be disposed on the bottom surface of the interposer 1200 and connected to the through electrode 1220. The interposer 1200 may be stacked on the package substrate 1100 via the second connection terminal 1250. Second connection terminals 1250 may be respectively connected to pads on the top surface of the interposer 1200 through the through electrodes 1220 and wiring lines of the wiring layer 1210.

In the system package 2000 of an embodiment, the interposer 1200 may be used for converting or transmitting electrical signals between the first semiconductor package 1000 and the semiconductor device 1300. Therefore, the interposer 1200 may not include components such as active devices or passive devices. However, according to some embodiments, the interposer 1200 may include devices for controlling signal transmission. An underfill 1260 may be disposed in a space between the interposer 1200 and the package substrate 1100 and a space between the second connection terminals 1250. For example, the space between the interposer 1200 and the package substrate 1100 and the space between the second connection terminals 1250 may be filled with the underfill 1260. According to other embodiments, the underfill 1260 may be replaced with an adhesive layer such as an adhesive film.

Semiconductor devices 1300 may be stacked on the central portion of the interposer 1200 via a third connection terminal 1350. For example, the third connection terminal 1350 may be disposed in the central portion of the interposer 1200. The semiconductor device 1300 may have a chip structure or a package structure. In the system package 2000 according to an embodiment, the semiconductor device 1300 may have a chip structure. For example, the semiconductor device 1300 may include a logic chip. The semiconductor device 1300 may include a plurality of logic devices therein. The logic devices may include, for example, AND devices, NAND devices, OR devices, NOR devices, XOR devices, XNOR devices, INV devices, ADD devices, DLY devices, FIL devices, MXT/MXIT devices, OAI devices, AO devices, AOI devices, D flip-flop devices, reset flip-flop devices, master-slaver flip-flop devices, latch devices, counters, or buffer devices. The logic devices may perform various signal processing such as analog signal processing, analog-to-digital conversion, and/or controlling. The semiconductor device 1300 may be referred to as a central processing unit (CPU) chip, a system-on-glass (SOG) chip, a micro-processor unit (MPU) chip, a graphics processing unit (GPU) chip, a neural processing unit (NPU) chip, an application processor (AP) chip, or a control chip, depending on the function thereof.

In the system package 2000 according to an embodiment, the semiconductor device 1300 may have a chip structure, wherein the semiconductor device 1300 may have an SoC structure or a chiplet structure. A semiconductor device 1300 may be a chiplet when it functions as a modular, independent component within the system package 2000. The SoC structure may have a structure in which a plurality of systems may be integrated into a single chip, as shown in FIG. 6A. Therefore, the semiconductor device 1300 having the SoC structure may perform operational functions, data storage, analog and digital signal conversion within a single chip. However, embodiments are not limited thereto, and the semiconductor device 1300 having the SoC structure may perform other functions. The semiconductor device 1300 having the SoC structure of FIG. 6A may include, for example, a CPU region 1310, a GPU region 1320, an I/O region 1330, a communication region 1340, and another region 1360 therein.

The chiplet structure may have a structure in which a logic chip is divided into separate chips according to functions thereof, as shown in FIG. 6B, and divided chips may be connected to one another. For example, the semiconductor device 1300a having the chiplet structure of FIG. 6B may include a CPU chip 1310a, a GPU chip 1320a, an I/O chip 1330a, a communication modem chip 1340a, and another function chip 1360a. The semiconductor device 1300a having such the chiplet structure may overcome one or more performance limitations of a single chip.

The external sealing member 1500 may cover the semiconductor device 1300 and the semiconductor package 1000 on the interposer 1200. The external sealing member 1500 may seal the semiconductor device 1300 and the semiconductor package 1000 on the interposer 1200, and may protect the semiconductor device 1300 and the semiconductor package 1000 on the interposer 1200 from an external contaminant or environment. As shown in FIG. 5B, the external sealing member 1500 may not cover the top surfaces of the semiconductor device 1300 and the semiconductor package 1000. However, according to other embodiments, the external sealing member 1500 may cover the top surface of at least one of the semiconductor device 1300 or the semiconductor package 1000. The system package 2000 according to an embodiment may further include a second external sealing member for covering and sealing the interposer 1200 and the external sealing member 1500 on the package substrate 1100.

For reference, the structure of the system package 2000 as provided in an embodiment is referred to a 2.5D package structure, wherein the 2.5D package structure may be a relative concept to a 3D package structure in which all semiconductor chips are stacked together and there is no interposer. Both the 2.5D package structure and the 3D package structure may be included in system-in-package (SIP) structures. Also, the system package 2000 according to an embodiment is also a semiconductor package, but is named as a system package to distinguish it from the semiconductor package 1000, which is a component.

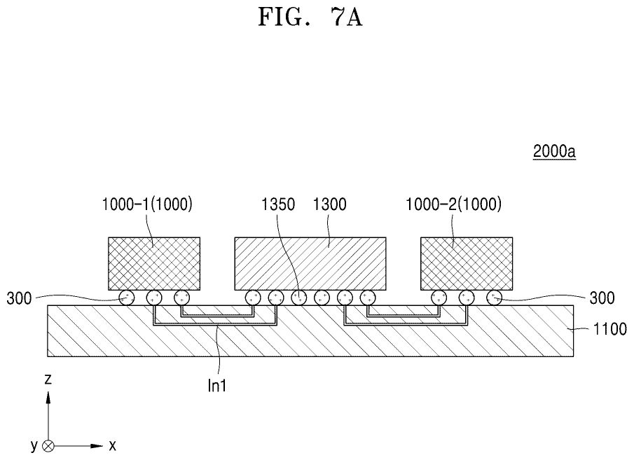

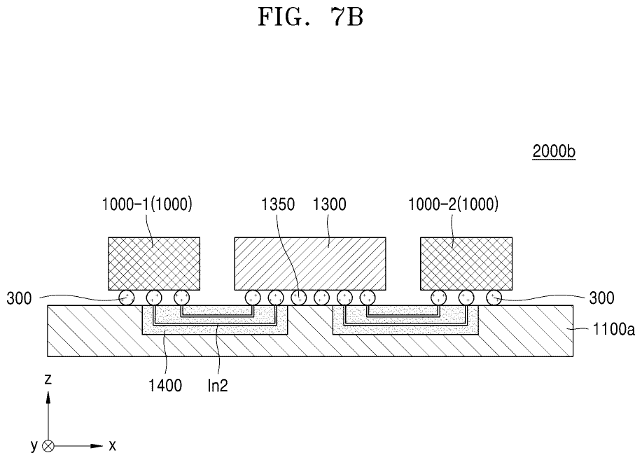

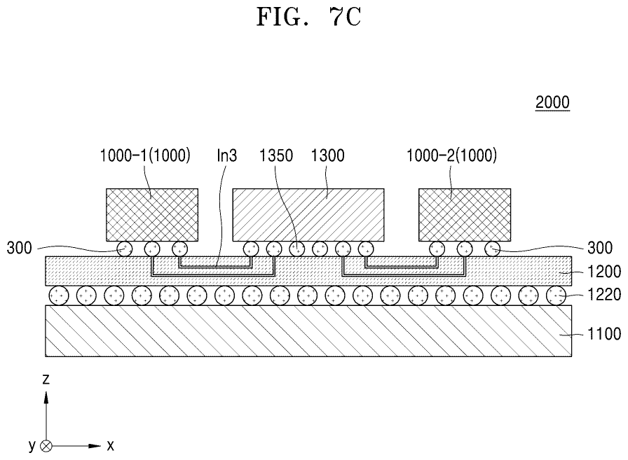

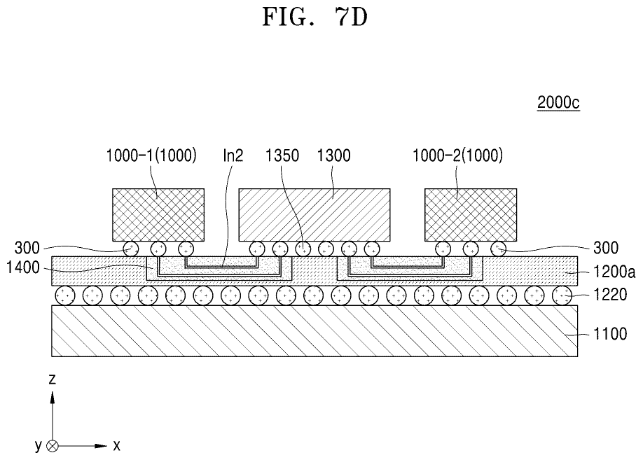

FIG. 7A, FIG. 7B, FIG. 7C, and FIG. 7D are cross-sectional views of system packages according to embodiments. Descriptions given elsewhere herein may be briefly given or omitted. Here, FIGS. 7A to 7D are cross-sectional views corresponding to FIG. 5B, and, from the perspective of the connection structure between the semiconductor package 1000 and the semiconductor device 1300, only the semiconductor package 1000, the mounting substrate 1100 or 1200, and the semiconductor device 1300 are schematically illustrated, and first connection terminals and external sealing members are not illustrated.

Referring to FIG. 7A, a system package 2000a according to an embodiment may include the semiconductor package 1000, the package substrate 1100, and the semiconductor device 1300. The system package 2000a according to an embodiment may not include an interposer, unlike the system package 2000 of FIG. 5B. Therefore, the semiconductor package 1000 may be mounted directly on the package substrate 1100 via the external connection terminal 300. Also, the semiconductor device 1300 may be mounted directly on the package substrate 1100 via the third connection terminal 1350. Detailed descriptions of structures and functions of the package substrate 1100, the semiconductor package 1000, and the semiconductor device 1300 may be substantially the same as those given herein in the description of the system package 2000 of FIG. 5B. As shown in FIG. 7A, in the system package 2000a according to an embodiment, the semiconductor package 1000 and the semiconductor device 1300 may be connected to each other through first connection wires In1 of the package substrate 1100. The first connection wires In1 may be some of wiring lines of the package substrate 1100.

Referring to FIG. 7B, a system package 2000b according to an embodiment may include the semiconductor package 1000, a package substrate 1100a, the semiconductor device 1300, and a Si-bridge 1400. The system package 2000b according to an embodiment may further include the Si-bridge 1400.

The Si-bridge 1400 may be disposed within the package substrate 1100a, as shown in FIG. 7B. The Si-bridge 1400 may be disposed inside the package substrate 1100a corresponding to a position between the semiconductor package 1000 and the semiconductor device 1300. Also, the Si-bridge 1400 may overlap a portion of the semiconductor package 1000 and a portion of the semiconductor device 1300. In the system package 2000b according to an embodiment, the semiconductor packages 1000 may be arranged on both sides of the semiconductor device 1300 in the x direction. Therefore, Si-bridges 1400 may be arranged on both sides of the semiconductor device 1300 in the x direction.

The Si-bridge 1400 may include second connection wires In2 therein. The Si-bridge 1400 may connect the semiconductor package 1000 and the semiconductor device 1300 to each other through the second connection wires In2. In other words, in the system package 2000b according to an embodiment, the semiconductor package 1000 and the semiconductor device 1300 may be connected to each other using the Si-bridge 1400 separately disposed within the package substrate 1100a.

Referring to FIG. 7C, the system package 2000 according to an embodiment may be substantially identical to the system package 2000 of FIG. 5B. Therefore, the system package 2000a according to an embodiment may include the semiconductor package 1000, the package substrate 1100, the interposer 1200, and the semiconductor device 1300. The semiconductor package 1000 may be mounted on the interposer 1200 via the external connection terminal 300, and the semiconductor device 1300 may be mounted on the interposer 1200 via the third connection terminal 1350. As shown in FIG. 7C, in the system package 2000 according to an embodiment, the semiconductor package 1000 and the semiconductor device 1300 may be connected to each other through third connection wires In3 of the interposer 1200. The third connection wires In3 may include a wiring line of the wiring layer 1210 and the through electrode 1220 or may include only a wiring line of the wiring layer 1210.

Referring to FIG. 7D, a system package 2000c according to an embodiment may include the semiconductor package 1000, the package substrate 1100, an interposer 1200a, the semiconductor device 1300, and the Si-bridge 1400. The system package 2000c according to an embodiment may further include the Si-bridge 1400.

The Si-bridge 1400 may be disposed within the interposer 1200a, as shown in FIG. 7D. The Si-bridge 1400 may be disposed inside the interposer 1200a corresponding to a position between the semiconductor package 1000 and the semiconductor device 1300. Also, the Si-bridge 1400 may overlap a portion of the semiconductor package 1000 and a portion of the semiconductor device 1300. In the system package 2000c according to an embodiment, the semiconductor packages 1000 may be arranged on both sides of the semiconductor device 1300 in the x direction. Therefore, Si-bridges 1400 may be arranged on both sides of the semiconductor device 1300 in the x direction.

The Si-bridge 1400 may include second connection wires In2 therein. The Si-bridge 1400 may connect the semiconductor package 1000 and the semiconductor device 1300 to each other through the second connection wires In2. In other words, in the system package 2000c according to an embodiment, the semiconductor package 1000 and the semiconductor device 1300 may be connected to each other using the Si-bridge 1400 separately disposed within the interposer 1200a.

While the inventive concept has been particularly shown and described with reference to embodiments thereof, it will be understood that various changes in form and details may be made therein without departing from the spirit and scope of the following claims.

What is claimed is:

1. A semiconductor package comprising:
a base chip;
a plurality of memory chips disposed on the base chip;
a sealing member disposed on the base chip and proximate to a side surface of the plurality of memory chips; and
a plurality of connection terminals disposed on a bottom surface of the base chip opposite the plurality of memory chips,
wherein the bottom surface of the base chip includes a first region and a second region disposed adjacent to the first region in the first direction,
the plurality of connection terminals comprise a plurality of first connection terminals on the first region and a plurality of second connection terminals on the second region, and
a first connection terminal of the plurality of first connection terminals is larger in size than a second connection terminal of the plurality of second connection terminals.

2. The semiconductor package of claim 1, wherein the first connection terminals are arranged on the first region at a first pitch, and
the second connection terminals are arranged on the second region at a second pitch, the second pitch being less than the first pitch.

3. The semiconductor package of claim 1, wherein the first connection terminal comprises a first pillar disposed on the bottom surface of the base chip and a first bump disposed on a bottom surface of the first pillar, and
the second connection terminal comprises a second pillar disposed on the bottom surface of the base chip and a second bump disposed on a bottom surface of the second pillar.

4. The semiconductor package of claim 3, wherein a height of the first pillar is greater than a height of the second pillar,
a diameter of the first pillar is greater than a diameter of the second pillar,
a height of the first bump is greater than a height of the second bump, and
a diameter of the first bump is greater than a diameter of the second bump.

5. The semiconductor package of claim 1, wherein the first connection terminal and the second connection terminal have a height difference sufficient to compensate for warpage of the base chip.

6. The semiconductor package of claim 1, wherein the plurality of second connection terminals disposed in the second region are electrically connected to an operation region of a logic chip disposed on the base chip.

7. The semiconductor package of claim 1, wherein the base chip comprises a buffer chip, and
each of the plurality of memory chips comprises a dynamic random access memory (DRAM) chip.

8. The semiconductor package of claim 1, wherein the semiconductor package comprises a high bandwidth memory (HBM) package.

9. A semiconductor package comprising:
a buffer chip;
a plurality of memory chips arranged on the buffer chip;
a sealing member disposed on the base chip and proximate to a side surface of the plurality of memory chips; and
a plurality of connection terminals disposed on a bottom surface of the buffer chip opposite the plurality of memory chips,
wherein the plurality of connection terminals comprise a plurality of first connection terminals on a first region of the bottom surface of the buffer chip and a plurality of second connection terminals on a second region of the bottom surface of the buffer chip,
the plurality of first connection terminals have a first pitch in a first direction and the plurality of second connection terminals have a second pitch in the first direction, the second pitch being less than the first pitch, and
a first connection terminal of the plurality of first connection terminals is larger in size than a second connection terminal of the plurality of second connection terminals.

10. The semiconductor package of claim 9, wherein the bottom surface of the buffer chip has a shape of a rectangle,
the first direction is a direction parallel to a first side of the rectangle,
the first region is disposed on a first side of the buffer chip in the first direction,
the second region is disposed adjacent to the first region on a second side in the first direction, and
the first region has a first width in the first direction, and the second region has a second width, the second width being less than the first width.

11. The semiconductor package of claim 9, wherein the first connection terminal and the second connection terminal have a height difference sufficient to compensate for warpage of the buffer chip.

12. The semiconductor package of claim 9, wherein the first connection terminal comprises a first pillar disposed on the bottom surface of the base chip and a first bump disposed on a bottom surface of the first pillar,
the second connection terminal comprises a second pillar disposed on the bottom surface of the base chip and a second bump disposed on a bottom surface of the second pillar,
wherein a height of the first pillar is greater than a height of the second pillar,
a diameter of the first pillar is greater than a diameter of the second pillar,
a height of the first bump is greater than a height of the second bump, and
a diameter of the first bump is greater than a diameter of the second bump.

13. A semiconductor package comprising:
a package substrate;
a first semiconductor device disposed on the package substrate; and
at least one second semiconductor device disposed on the package substrate and adjacent to the first semiconductor device,
wherein the second semiconductor device has a package structure comprising a base chip, a plurality of memory chips arranged on the base chip, a sealing member disposed on the base chip and proximate to a side surface of the plurality of memory chips, and a plurality of connection terminals disposed on a bottom surface of the base chip opposite the plurality of memory chips,
wherein the plurality of connection terminals comprise a plurality of first connection terminals on a first region of the bottom surface of the base chip and a plurality of second connection terminals on a second region of the bottom surface of the base chip, and
a first connection terminal of the plurality of first connection terminals is larger in size than a second connection terminal of the plurality of second connection terminals.

14. The semiconductor package of claim 13, wherein the first connection terminals are arranged on the first region at a first pitch, and
the second connection terminals are arranged on the second region at a second pitch, the second pitch being less than the first pitch.

15. The semiconductor package of claim 13, wherein the first connection terminal and the second connection terminal have a height difference sufficient to compensate for warpage of the base chip.

16. The semiconductor package of claim 13, wherein the first connection terminal comprises a first pillar disposed on the bottom surface of the base chip and a first bump disposed on a bottom surface of the first pillar,
the second connection terminal comprises a second pillar disposed on the bottom surface of the base chip and a second bump disposed on a bottom surface of the second pillar,
the first pillar is larger in size than the second pillar, and
the first bump is larger in size than the second bump.

17. The semiconductor package of claim 13, wherein the first semiconductor device comprises at least one logic chip, and
the second semiconductor device comprises a high bandwidth memory (HBM) package.

18. The semiconductor package of claim 13, wherein the first semiconductor device comprises a plurality of logic chips, and
the second connection terminal is connected to an operational logic chip from among the plurality of logic chips.

19. The semiconductor package of claim 13, further comprising an intermediate substrate disposed on the package substrate,
wherein the first semiconductor device and the second semiconductor device are arranged on the intermediate substrate and are connected to each other through the intermediate substrate.

20. The semiconductor package of claim 13, further comprising a silicon bridge disposed within the package substrate,
wherein the first semiconductor device and the second semiconductor device are connected to each other through the silicon bridge.
